(19) United States
(12) Patent Application Publication
(10) Pub. No.: US 2010/0085715 A1
(43) Pub. Date: Apr. 8, 2010

(54) PRINTED ELECTRONIC COMPONENT ASSEMBLY ENABLED BY LOW TEMPERATURE PROCESSING

(75) Inventors: Steven M. Scheifers, Hoffman Estates, IL (US); Hope W. Chik, Windham, NH (US); Andrew F. Skipor, West Chicago, IL (US)

Correspondence Address: MOTOROLA, INC., 1303 EAST ALGONQUIN ROAD, IL01/3RD, SCHAUMBURG, IL, 60196, US

(73) Assignee: Motorola, Inc., Schaumburg, IL (US)

(21) Appl. No.: 12/247,150

(22) Filed: Oct. 7, 2008

(51) Int. Cl. H05K 3/22; H05K 1/14

(52) U.S. Cl. 361/743; 29/593

(57) ABSTRACT

A manufacturing method and manufacturing system for creating a modular electronic assembly are disclosed. The manufacturing system 300 may position a contact terminal 202 of a printed electronic component module 102 relative to a contact pad 204 of a printed electronic substrate 112. The manufacturing system 300 may connect the contact terminal 202 to the contact pad 204 using a conductive adhesive connection 116.

### FIELD OF THE INVENTION

The present invention relates to a method and system for creating a printed electronic assembly. The present invention further relates to creating a set of printed electronic component modules to be joined together to create a printed electronic assembly.

### INTRODUCTION

Tape automated bonding (TAB) may locate and bond components and small circuits to printed wire boards, by mounting a die on a flexible tape made of polymer material, such as polyimide. The mounting may be done such that the bonding sites of the die, usually in the form of bumps or balls made of gold or solder, are connected to fine conductors on the tape, providing the means of connecting the die to the package or directly to external circuits. Sometimes the tape on which the die is bonded may already contain the actual application circuit of the die.

The TAB bonds connecting the die and the tape may be inner lead bonds (ILB), while those that connect the tape to the package or to external circuits may be outer lead bonds (OLB).

The gold bump of the die and the lead of a TAB circuit may be bonded by single-point thermosonic bonding or gang or thermocompression bonding.

Single-point bonding, as the name implies, may connect each of the die's bond site individually to a corresponding lead on the tape. Heat, time, force, and ultrasonic energy may be applied to the TAB lead, which is positioned directly over the gold bump, forming intermetallic connections between them in the process. Single-point bonding may be a more time-consuming process than gang bonding.

Gang bonding may employ a specially designed bonding tool to apply force, temperature, and time to create diffusion bonds between the leads and bumps, all at the same time. Gang bonding may offer a higher throughput rate to single-point bonding.

### SUMMARY OF THE INVENTION

A manufacturing method and manufacturing system for creating a modular printed electronic assembly are disclosed. The manufacturing system may position a contact terminal of a printed electronic component module relative to a contact pad of a printed electronic substrate. The manufacturing system may connect the contact terminal to the contact pad using a low temperature manufacturing process, such as traditional adhesive, nano-attachment methods, or nano-solder.

### BRIEF DESCRIPTION OF THE DRAWINGS

Understanding that these drawings depict only typical embodiments of the invention and are not therefore to be considered to be limiting of its scope, the invention will be described and explained with additional specificity and detail through the use of the accompanying drawings in which:

FIG. 1 illustrates in a block diagram one embodiment of a modular printed electronic assembly.

FIG. 2 illustrates in a block diagram a conductive adhesive connection.

FIG. 3 illustrates in a block diagram one embodiment of a modular printed electronic assembly manufacturing system.

FIG. 4 illustrates in a flowchart one embodiment of a method for manufacturing a modular printed electronic assembly.

FIG. 5 illustrates in a flowchart one embodiment of a method for repairing a modular printed electronic assembly.

FIG. 6 illustrates a possible configuration of a computing system to act as a control system for a manufacturing system.

### DETAILED DESCRIPTION OF THE INVENTION

Additional features and advantages of the invention will be set forth in the description which follows, and in part will be obvious from the description, or may be learned by practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth herein.

Various embodiments of the invention are discussed in detail below. While specific implementations are discussed, it should be understood that this is done for illustration purposes only. A person skilled in the relevant art will recognize that other components and configurations may be used without parting from the spirit and scope of the invention.

The present invention comprises a variety of embodiments, such as a method, a modular electronic assembly, and a manufacturing system, and other embodiments that relate to the basic concepts of the invention. The manufacturing system may be controlled by any manner of computer, mobile device, or wireless communication device.

A manufacturing method and manufacturing system for creating a modular printed electronic assembly are disclosed. The modular printed electronic assembly may be created from a set of one or more electronic component modules, such as printed electronic component modules, connected together, or connected to electronic devices or electronic printed circuit boards.

The manufacturing system may position a contact terminal of a printed electronic component module relative to a contact pad of a printed electronic substrate. The manufacturing system may connect the contact terminal to the contact pad using a conductive adhesive connection.

Printed electronics may be created by using standard printing techniques to create an electronic device on a substrate made of a common media such as paper, plastic, textile, or other surface. The electronic substrate of a printed electronic assembly, or printed electronic substrate, may be any of a number of commercially available polymers, such as polyamide, polyimide, polyetherimide, polysiloxane, polyurethane, polyamide-imide, polyester, polyacrylate, paper, or other polymers and combinations of polymers. The printing process may be a contact printing process, such as stamping, screen printing, flexographic, micro-contact printing, and other contact printing processes, or a non-contact printing process, such as ink jet, electrostatic, laser transfer, and micro-dispensing, and other non-contact printing processes. Contact terminals may be created by depositing a conducting metal, such as a chromium-gold, titanium-gold, aluminum, conductive ink, or other electrically conducting structure, or by using print and etch techniques on substrates with conductive films such as aluminized mylar.

Semi-conducting devices may be created by depositing either an organic or inorganic semiconducting material on the printed electronic substrate between the contact terminals. The organic semiconducting material may be polythiophene, polyacetylene, phthalocyanine, poly(3-hexylthiophene), poly(3-alkylthiophene), α-ω-hexathiophene, pentacene, α-ω-dihexyl-hexathiophene, polythienylenevinylene, bis(dithienothiophene), α-ω-dihexyl-quaterthiophene, dihexyl-anthradithiophene, n-decapentafluoroheptyl-methyl-naphthalene-1,4,5,8-tetracarboxylic diimide, α-ω-dihexyl-quinquethiophene, or other organic semiconducting material. Inorganic semiconductors, such as silicon, gallium, gallium-arsenide, or other type II-V and type II-VI semiconductors; metal oxides, such as ZnO, SnO2, NiO, and combinations thereof; and solution processed semiconductors, such as quantum dots, may be print deposited as nano-particles suspended in a carrier, such as alkyl alcohols, alkyl diols, alkyl polyols, water, hexane, acetone, methylene chloride, alkyl polyol acetates or other liquid solvents. The carrier may be removed by low heat drying.

Because of the vulnerability of the printed electronic assemblies to damage by the high temperatures normally associated with connecting electrical components, printed electronic assemblies generally involve designing an entire assembly. Modularizing a printed electronic assembly may provide greater flexibility in printed electronic assembly design. Instead of printing an entire electronic assembly, a manufacturer may print each electronic component of the electronic assembly separately, and then assemble the electronic assembly. The individualized printing process may permit each component of the electronic assembly to be individually tested. As innovations improve different components, the improved printed electronic component modules may be swapped out to improve the entire printed electronic assembly. Further, damaged printed electronic component modules may be swapped out with new printed electronic component modules, without the use of high temperature assembly processes.

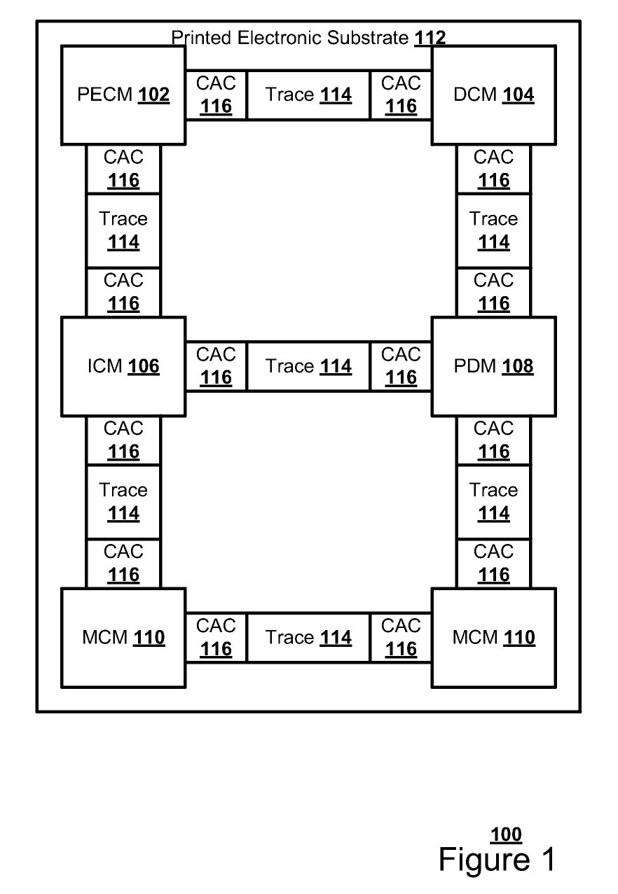

FIG. 1 illustrates in a block diagram one embodiment of a modular printed electronic assembly 100. A modular printed electronic assembly (MPEA) 100 may integrate complex printed assemblies that are not amenable to web-like or sheet fed printing, such as electron driven quantum dot emission. A MPEA 100 may be made up of a number of printed electronic component modules 102. A printed electronic component module (PECM) 102 may be any printed electronic device, either as a unitary device or as a subset of an overall printed electronic assembly. A PECM 102 may be created using the printing techniques and materials described above. A PECM 102 may be a discrete component module (DCM) 104, such as a transistor; an integrated circuit module 106, such as a printed AND circuit; or a printed device module (PDM 108, such as a battery, a display, or an organic light-emitting diode (OLED). The PECM 102 may be a flexible component manufactured using a reel to reel or printing web process. The MPEA 100 may include a microelectronic circuit module (MCM) 110, or a circuit module not created by device printing techniques.

A set of PECMs 102 and MCMs 110 may be mounted onto an electronic substrate 112. The electronic substrate 112 may be a regular substrate such as a traditional board or semiconductor, such as a silicon semiconductor. Alternately, the substrate 112 may be a printed electronic substrate 112. The printed electronic substrate 112 may be selected from a variety of materials, including a plastic, paper, textile, or other media. The printed electronic substrate 112 may itself be a part of a second PECM 102 or of a printed circuit board. The printed electronic substrate 112 may have one or more printed traces 114 to interconnect each PECM 102. A contact terminal of a first PECM 102 may be connected to a first conductive adhesive connection (CAC) 116 attached to a first end of a printed trace 114 of the printed electronic substrate 112. The printed trace may be attached at a second end by a second CAC 116 to a contact terminal of a second PECM 102. The first PECM 102 may send an electrical signal to the second PECM 102 via the printed trace and CAC 116.

The CAC 116 may adhere to a contact terminal of the PECM 102 by using a low temperature or even room temperature connection method, to prevent damage to the PECM 102 during the connection process. The CAC 116 may be a nano-solder connection, having a melting point below 150° Celsius. Traditional tin-lead eutectic alloy melts at 183° Celsius, while non-lead (Pb) tin-silver-copper alloys have melting points around 220° Celsius. A nano-solder connection may be high energy solid metal and metal alloy to create a soldering composition that may reduce the reflow temperature of solder interconnects by depressing the melting point. Reduced temperatures may facilitate the use of existing manufacturing lines and electronic components, and minimize the cost impact of transition to a no-lead solder. The CAC 116 may be an elastomeric connector or an anisotropic electrical connector. The CAC 116 may be a low temperature metal filled adhesive, such as a B-staged silver filled epoxy. The CAC 116 may be constructed from one or more engineered nanostructured surfaces assembled together.

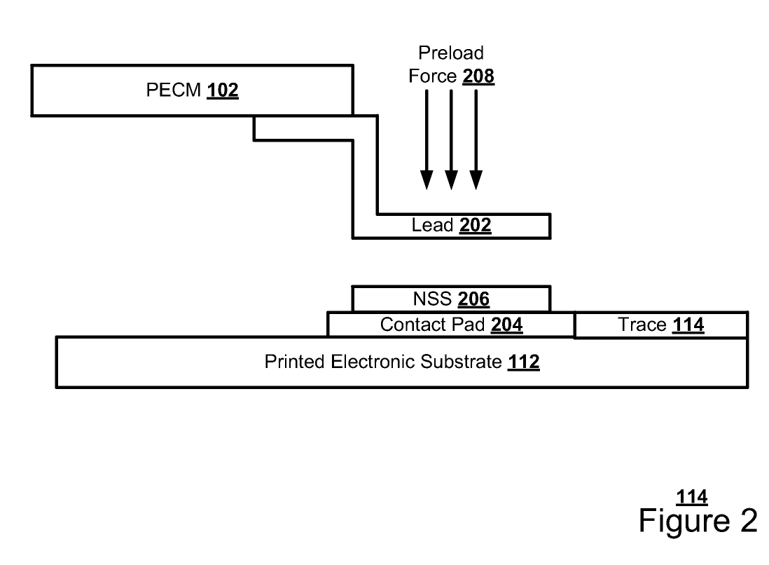

FIG. 2 illustrates in a block diagram one embodiment of a method of attaching the PECM 102 to the printed electronic substrate using a nanostructured surface assembly. The contact terminal PECM 102 may be a lead 202 to pass electrical communication signals to be passed to the printed electronic substrate 112. A printed trace 114 or contact terminal of the printed electronic substrate 112 may have a contact pad 204 to receive those electrical communication signals. The contact pad 204 may have a nanostructured surface (NSS) 206 with weaker intermolecular forces to adhere to the lead 202 of the PECM 102. A preload force may be applied to the lead 202 and contact pad 204 to create an adhesion between the lead 202 and the NSS 206 via van der Waals forces. The NSS 206 may be engineered to create adhesion in room temperature conditions, yet remain extremely stable in wide range of adverse environments, such as high temperatures, humidity, chemical exposure, ultraviolet radiation, and other adverse conditions. Further, the NSS 206 may be engineered to have multiple attachments and detachments without loss of adhesion.

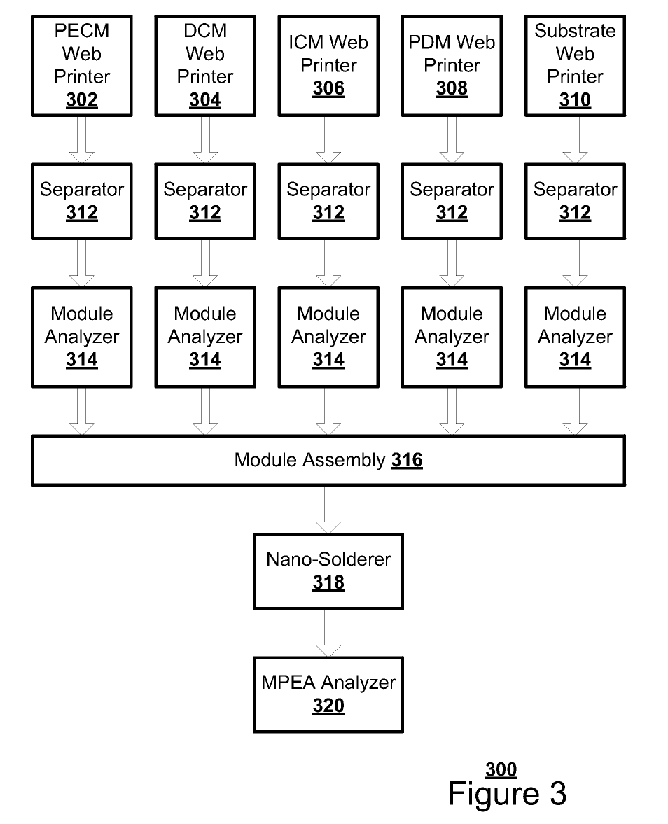

FIG. 3 illustrates in a block diagram one embodiment of a MPEA manufacturing system 300. A PECM web printer 302 may print multiple PECMs 102 using web printing technology. Additionally, a DCM web printer 304 may may use web printing technology to create multiple DCMs 104, an ICM web printer 304 may create multiple ICMs 106 with this same technology, a PDM web printer 308 may print multiple PDMs 108 with this technology, and a substrate web printer 310 may print multiple printed electronic substrates 112 using web based printing technology.

A separator 312 may divide the web of PECMs 102 into separate PECMs 102. A module analyzer 314 may test each PECM 102 to make sure that the PECM 102 is viable. A module assembler 316 may assemble the appropriate PECMs 102, arranging them and connecting them to the printed electronic substrate 112 to create the desired MPEA 100. A nano-soldering device 318, or other device capable of nano-attachment, may create the necessary CAC 116 to allow PECMs 102 to transmit signals and communicate with each other. A MPEA analyzer 320 may test the assembled and connected MPEA 100 to make sure that MPEA works as designed and to ensure that the MPEA 100 was not damaged during the manufacturing process.

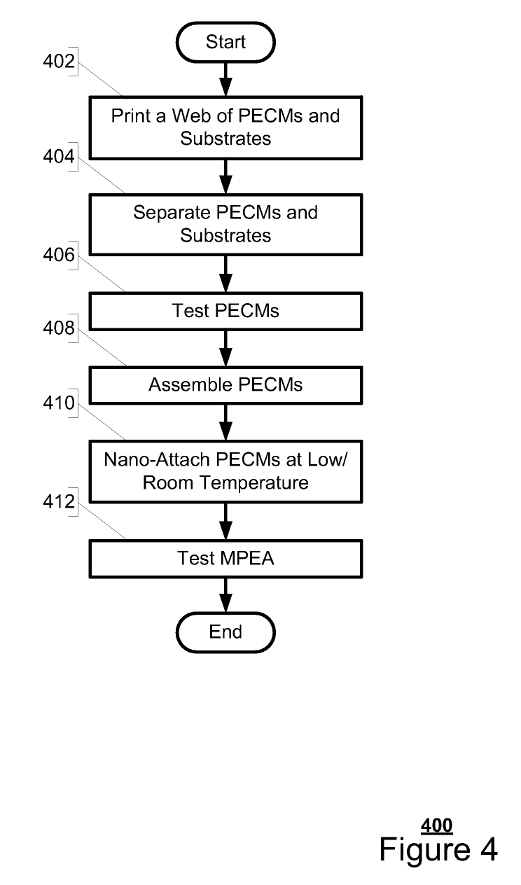

FIG. 4 illustrates in a flowchart one embodiment of a method 400 for manufacturing a MPEA 100. The PECM web printer 302 may print a web of PECMs 102 and a web of printed electronic substrates 112 (Block 402). The separators 312 may separate the web of PECMs 102 into a set of PECMs 102 and the web of printed electronic substrates 112 into a set of printed electronic substrates 112 (Block 404). The module analyzers 314 may test the PECMs 102 for viability (Block 406). The module assembly 316 may arrange the PECMs 102 into the designed MPEA 100 (Block 408). The manufacturing system 300 may nano-attach the PECMs 102 at low or even room temperature to the printed electronic substrate 112 (Block 410). The nano-attachment device may create the nano-attachment at sub-ambient temperatures. The MPEA analyzer 320 may test the MPEA 100 (Block 412).

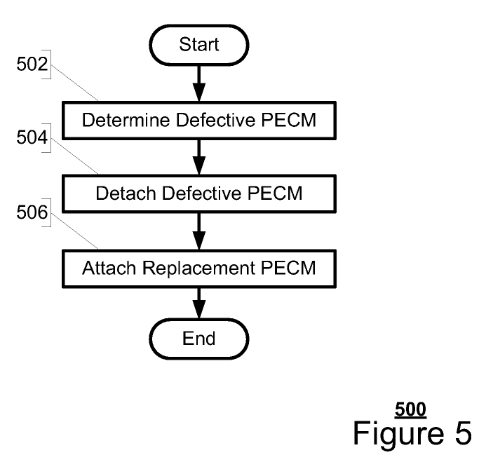

FIG. 5 illustrates in a flowchart one embodiment of a method 500 for repairing a MPEA 100. A MPEA analyzer 320 may determine which PECM 102 in the MPEA 100 is defective (Block 502). A knife, laser, or other precision cutting device may then sever the CAC 116 from the defective PECM 102 and detach the defective PECM 102 (Block 504). The nano-attachment device may nano-attach a replacement PECM 102 (Block 506). Other configurations and implementations may use other CAC possibilities such as silver filled epoxy.

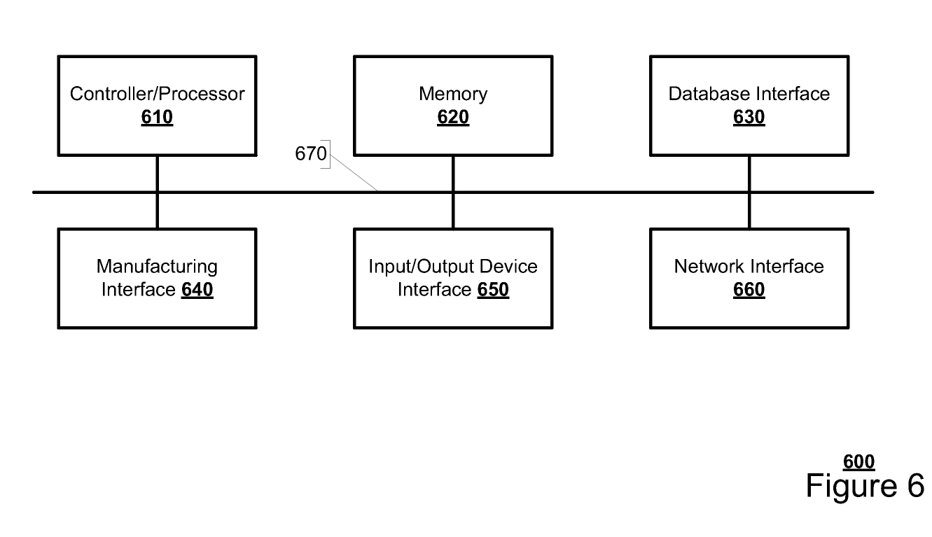

FIG. 6 illustrates a possible configuration of a computing system to act as a control system 600 for the manufacturing system 300. The control system 600 may include a controller/processor 610, a memory 620, a database interface 630, a manufacturing interface 640, input/output (I/O) device interface 650, and a network interface 660, connected through bus 670. The control system 600 may implement any operating system, such as Microsoft Windows®, UNIX, or LINUX, for example. Control software may be written in any programming language, such as C, C++, Java or Visual Basic, for example.

The controller/processor 610 may be any programmed processor known to one of skill in the art. However, the decision support method may also be implemented on a general-purpose or a special purpose computer, a programmed microprocessor or microcontroller, peripheral integrated circuit elements, an application-specific integrated circuit or other integrated circuits, hardware/electronic logic circuits, such as a discrete element circuit, a programmable logic device, such as a programmable logic array, field programmable gate-array, or the like. In general, any device or devices capable of implementing the decision support method as described herein may be used to implement the decision support system functions of this invention.

The memory 620 may include volatile and nonvolatile data storage, including one or more electrical, magnetic or optical memories such as a random access memory (AM), cache, hard drive, or other memory device. The memory may have a cache to speed access to specific data. The memory 620 may also be connected to a compact disc-read only memory (CD-ROM, digital video disc-read only memory (DVD-ROM), DVD read write input, tape drive, or other removable memory device that allows media content to be directly uploaded into the system.

Control data and MPEA designs may be stored in the memory or in a separate database. The database interface 630 may be used by the controller/processor 610 to access the database. The manufacturing interface 640 may allow control commands to be sent to any of the devices in the manufacturing system, as well as receive feedback from any of those devices.

The I/O device interface 650 may be connected to one or more input devices that may include a keyboard, mouse, pen-operated touch screen or monitor, voice-recognition device, or any other device that accepts input. The I/O device interface 650 may also be connected to one or more output devices, such as a monitor, printer, disk drive, speakers, or any other device provided to output data. The I/O device interface 650 may receive a data task or connection criteria from a network administrator.

The network connection interface 660 may be connected to a communication device, modem, network interface card, a transceiver, or any other device capable of transmitting and receiving signals from a network. The network connection interface 660 may be used to connect a client device to a network. The network connection interface 660 may be used to connect the control system to the network to allow remote access and control of the manufacturing system 300. The components of the control system 600 may be connected via an electrical bus 670, for example, or linked wirelessly.

Client software and databases may be accessed by the controller/processor 610 from memory 620, and may include, for example, database applications, as well as components that embody the decision support functionality of the present invention. The control system 600 may implement any operating system, such as Microsoft Windows®, LINUX, or UNIX, for example. Client and server software may be written in any programming language, such as C, C++, Java or Visual Basic, for example. Although not required, the invention is described, at least in part, in the general context of computer-executable instructions, such as program modules, being executed by the electronic device, such as a general purpose computer. Generally, program modules include routine programs, objects, components, data structures, etc. that perform particular tasks or implement particular abstract data types. Moreover, those skilled in the art will appreciate that other embodiments of the invention may be practiced in network computing environments with many types of computer system configurations, including personal computers, hand-held devices, multi-processor systems, microprocessor-based or programmable consumer electronics, network PCs, minicomputers, mainframe computers, and the like.

Embodiments within the scope of the present invention may also include computer-readable media for carrying or having computer-executable instructions or data structures stored thereon. Such computer-readable media can be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium which can be used to carry or store desired program code means in the form of computer-executable instructions or data structures. When information is transferred or provided over a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable media.

Embodiments may also be practiced in distributed computing environments where tasks are performed by local and remote processing devices that are linked (either by hardwired links, wireless links, or by a combination thereof) through a communications network.

Computer-executable instructions include, for example, instructions and data which cause a general purpose computer, special purpose computer, or special purpose processing device to perform a certain function or group of functions. Computer-executable instructions also include program modules that are executed by computers in stand-alone or network environments. Generally, program modules include routines, programs, objects, components, and data structures, etc. that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Although the above description may contain specific details, they should not be construed as limiting the claims in any way. Other configurations of the described embodiments of the invention are part of the scope of this invention. For example, the principles of the invention may be applied to each individual user where each user may individually deploy such a system. This enables each user to utilize the benefits of the invention even if any one of the large number of possible applications do not need the functionality described herein. In other words, there may be multiple instances of the electronic devices each processing the content in various possible ways. It does not necessarily need to be one system used by all end users. Accordingly, the appended claims and their legal equivalents should only define the invention, rather than any specific examples given.

1. A method for creating a modular printed electronic assembly, comprising:
positioning a contact terminal of a printed electronic component module relative to a contact pad of a electronic substrate;
adhering the contact terminal to the contact pad using a conductive adhesive connection.

2. The method of claim 1, further comprising:
web printing the printed electronic component module.

3. The method of claim 1, wherein the first conductive adhesive connection have a melting point below 150° Celsius.

4. The method of claim 1, further comprising:
adhering the contact terminal to the contact pad at room temperature.

5. The method of claim 1, wherein the conductive adhesive connection is at least one of a nano-solder, an elastomeric connecter, an anisotropic electrical connecter, or a B-staged silver-filled epoxy.

6. The method of claim 1, wherein the conductive adhesive connection is a nano-structured surface.

7. The method of claim 1, further comprising:
connecting a microelectronic circuit module to the electronic substrate.

8. The method of claim 1, further comprising
detaching the contact terminal of the printed electronic module from the contact pad;
removing the printed electronic component module;
positioning a contact terminal of a replacement printed electronic component module relative to a contact pad of a electronic substrate;
adhering the contact terminal of the replacement printed electronic component module to the contact pad using a conductive adhesive connection.

9. The method of claim 1, further comprising
determining if the printed electronic component module is defective.

10-20. (canceled)
